(19) United States
(12) Patent Application Publication
(10) Pub. No.: US 2026/0304754 A1
(43) Pub. Date: Oct. 1, 2026

(54) SEMICONDUCTOR DEVICE AND FABRICATION METHOD THEREOF

(71) Applicant: Yangtze Memory Technologies Holding Co., Ltd., Wuhan (CN)

(72) Inventors: Danyang WEI, Wuhan (CN); Zongliang HUO, Wuhan (CN); Zichen LIU, Wuhan (CN); Yaqin LIU, Wuhan (CN); Liang CHEN, Wuhan (CN); Wei LIU, Wuhan (CN)

(21) Appl. No.: 19/272,681

(22) Filed: Jul. 17, 2025

Related U.S. Application Data
(63) Continuation of application No. PCT/CN2025/086590, filed on Apr. 1, 2025.

(51) Int. Cl. H10B 12/00; H01L 23/00; H01L 23/528; H10B 80/00; H10D 80/30

(52) U.S. Cl. CPC H10B 12/482; H10B 12/02; H10B 80/00; H10D 80/30; H10W 20/43; H10W 20/435; H10W 90/732

(57) ABSTRACT

Methods, devices, systems, and techniques for managing conductive structures in semiconductor device are provided. In one aspect, a semiconductor device includes bit lines having at least a first bit line extending along a first direction. The semiconductor device also includes conductive structures extending along the first direction, where the bit lines and the conductive structures are alternately arranged along a second direction perpendicular to the first direction. The semiconductor device further includes a semiconductor layer extending along a third direction perpendicular to the first direction and the second direction, where: the bit lines and the conductive structures are isolated by a dielectric material along the second direction; and the first bit line is connected to at least one memory cell including a semiconductor body and a storage structure arranged along the third direction.

### CROSS-REFERENCE TO RELATED APPLICATIONS

This application is a continuation of International Application No. PCT/CN2025/086590, filed on Apr. 1, 2025, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems and techniques for improv-ing sense margin in three-dimensional (3D) semiconductor devices.

One aspect of the present disclosure features a semiconductor device. The semiconductor device includes a memory cell array including memory cells arranged in a first direction, a second direction, and a third direction, where the second direction is perpendicular to the first direction, and the third direction is perpendicular to the first direction and the second direction. The semiconductor device also includes bit lines extending along the first direction, where the bit lines include at least a first bit line; and conductive structures extending along the first direction, where the bit lines and the conductive structures are alternately arranged along the second direction, where the bit lines and the conductive structures are isolated by a dielectric material along the second direction; the first bit line is connected to at least one memory cell of the memory cell array; and the at least one memory cell includes a semiconductor body and a storage structure arranged in the third direction.

In some implementations, the conductive structures are connected together.

In some implementations, the conductive structures are configured to be coupled to a fixed voltage equal to or smaller than a ground voltage.

In some implementations, the first bit line includes a wave portion and a straight portion along the first direction.

In some implementations, the semiconductor device further includes a semiconductor layer extending along a plane perpendicular to the first direction, where the bit lines are in contact with the semiconductor layer along the first direction, and where the conductive structures extend into the semiconductor layer along the first direction.

In some implementations, the bit lines further include a second bit line; the conductive structures include at least a first conductive structure and a second conductive structure; and the first conductive structure is adjacent to the first bit line along the second direction.

In some implementations, the first conductive structure extends beyond at least one end of the first bit line along the first direction.

In some implementations, a width of the first conductive structure along the third direction is greater than a width of the first bit line along the third direction.

In some implementations, a cross section of the first conductive structure perpendicular to the first direction has a rectangular shape or an ellipse shape.

In some implementations, the first conductive structure and the second conductive structure are connected to an interconnect structure along the first direction, where the interconnect structure extends along the second direction.

In some implementations, the first conductive structure and the second conductive structure are connected to one or more wires through respective contacts.

In some implementations, the first bit line is connected to a first wire through a first contact, the second bit line is connected to a second wire through a second contact.

In some implementations, the first conductive structure is connected to a third wire through a third contact, the second conductive structure is connected to a fourth wire through a fourth contact, the first wire, the second wire, the third wire, and the fourth wire are located on a same side of the bit lines, extend along the third direction, and are separated from one another.

In some implementations, the first conductive structure is connected to a third wire through a third contact, the second conductive structure is connected to the third wire through a fourth contact, the first wire, the second wire, and the third wire are located on a same side of the bit lines, extend along the second direction, and are separated from one another.

In some implementations, the first conductive structure is connected to a third wire through a third contact, the second conductive structure is connected to the third wire through a fourth contact, the third wire extends along the second direction, the first wire and the second wire are located on a same side of the bit lines, the first wire and the third wire are on opposite sides of the bit lines.

Another aspect of the present disclosure features a semiconductor device. The semiconductor device includes bit lines extending along a first direction; isolation structures extending along the first direction; and a semiconductor layer extending in a plane perpendicular to the first direction, where the bit lines are in contact with the semiconductor layer along the first direction; the bit lines and the isolation structures are arranged in a line extending along a second direction perpendicular to the first direction; the bit lines and the isolation structures alternate with one another along the second direction; and the bit lines and the isolation structures are isolated by a dielectric material along the second direction.

In some implementations, the at least one of the isolation structures includes a conductive structure.

In some implementations, the at least one of the isolation structures includes an airgap.

A further aspect of the present disclosure features a method of forming a semiconductor device. The method includes forming a memory cell array including memory cells arranged in a first direction, a second direction, and a third direction, where the second direction is perpendicular to the first direction, and the third direction is perpendicular to the first direction and the second direction; forming bit lines extending along the first direction, where the bit lines include at least a first bit line; and forming conductive structures extending along the first direction, where the bit lines and the conductive structures are alternately arranged along the second direction, where the bit lines and the conductive structures are isolated by a dielectric material along the second direction; the first bit line is connected to at least one memory cell of the memory cell array; and the at least one memory cell includes a semiconductor body and a storage structure arranged in the third direction.

In some implementations, providing a semiconductor structure having the bit lines extending along the first direction, where the bit lines are separated by sacrificial structures along the second direction, and where the sacrificial structures include a sacrificial material surrounded by a dielectric layer; removing the sacrificial material in the sacrificial structures by an etching process to form first trenches; and filling a conductive material into the first trenches to form the conductive structures.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A is a perspective view of an example three-dimensional (3D) semiconductor device.

FIG. 1B-1C are cross-sectional views of an example semiconductor device.

FIG. 1D is a top view of the example semiconductor device of FIG. 1B.

FIG. 1E-1F are cross-sectional views of an example semiconductor device.

FIG. 1G is a top view of the example semiconductor device of FIG. 1E.

FIG. 2A-2C are perspective views of an example 3D semiconductor device.

FIG. 3A-3C are top views of an example semiconductor device.

FIG. 3D is a cross-sectional view of the example semiconductor device of FIG. 3C.

FIG. 4A-4C show cross-sectional views of structures of a semiconductor device of FIG. 1B at various stages of a fabrication process.

FIG. 5A-5C show cross-sectional views of structures of a semiconductor device of FIG. 1E at various stages of a fabrication process.

FIG. 6 illustrates a flow chart of an example semiconductor structure manufacturing process.

FIG. 7 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, a memory device (e.g., a DRAM memory) can be formed with a 3-dimensional (3D) structure featuring multiple stacking layers. However, this design may pose challenges to device operations. For example, the multiple stacking layers require an array of bit lines to control the 3D memory device. These bit lines are separated by dielectric fillings, which form capacitors between adjacent bit lines. These capacitors may increase the coupling effect between adjacent bit lines. In other words, the capacitors between adjacent bit lines may reduce the sense margin of the memory device, potentially increasing the error rate during device operation. Therefore, a 3D structure that can address these issues is desirable.

In one or more implementations of the present disclosure, an example semiconductor device is provided. The semiconductor device includes bit lines extending along a first direction, where the bit lines include at least a first bit line. The semiconductor device also includes conductive structures extending along the first direction, where the bit lines and the conductive structures are alternately arranged along a second direction perpendicular to the first direction; and a semiconductor layer extending along a third direction perpendicular to the first direction and the second direction, where: the bit lines and the conductive structures are isolated by a dielectric material along the second direction; and the first bit line is connected to at least one memory cell including a transistor and a storage structure, the transistor extending along the third direction.

Implementations of the present disclosure can provide one or more of the following technical advantages and/or benefits. First, the memory device in the present disclosure includes conductive structures, each of which is positioned between two adjacent bit lines. These conductive structures are coupled to the ground and can be used as metal shielding for the memory device. In other words, the conductive structures can help reduce the coupling effect between the bit lines and improve the sense margin of the memory device. Second, in some implementations of the present disclosure, the conductive structures can be replaced by airgaps. Compared to the dielectric fillings used in current implementations, the airgaps in the present disclosure have a lower dielectric permittivity, which reduces the capacitance of a capacitor between two adjacent bit lines. In other words, the airgaps in the present disclosure may reduce the coupling effect between the two adjacent bit lines, thereby improving the sense margin of the memory device. Third, the conductive structures and the airgaps can be easily integrated into the existing device, which reduces fabrication costs.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

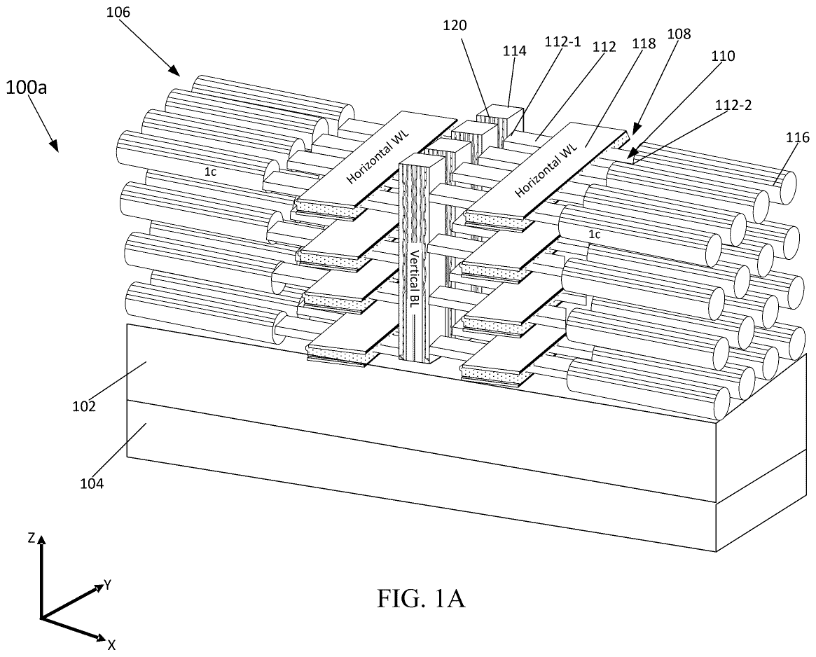

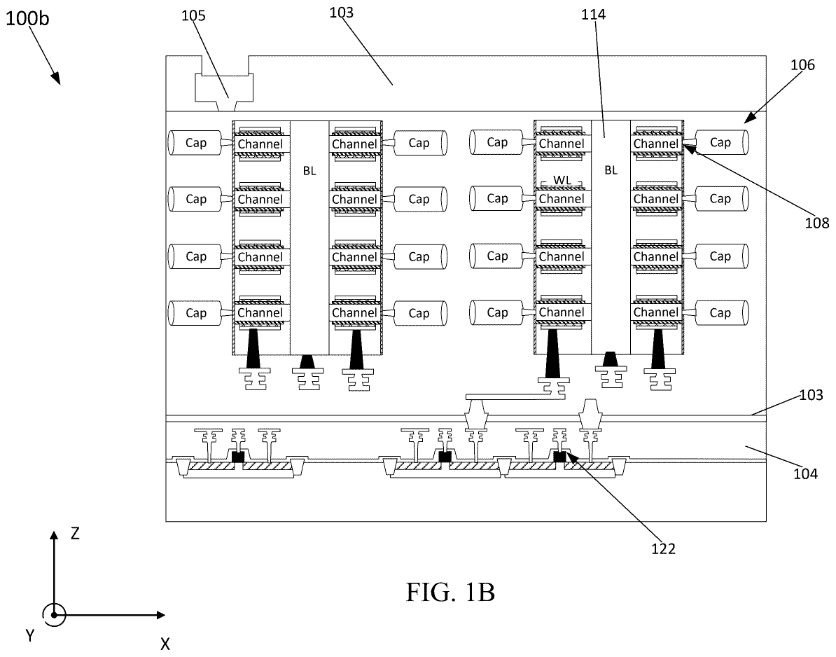

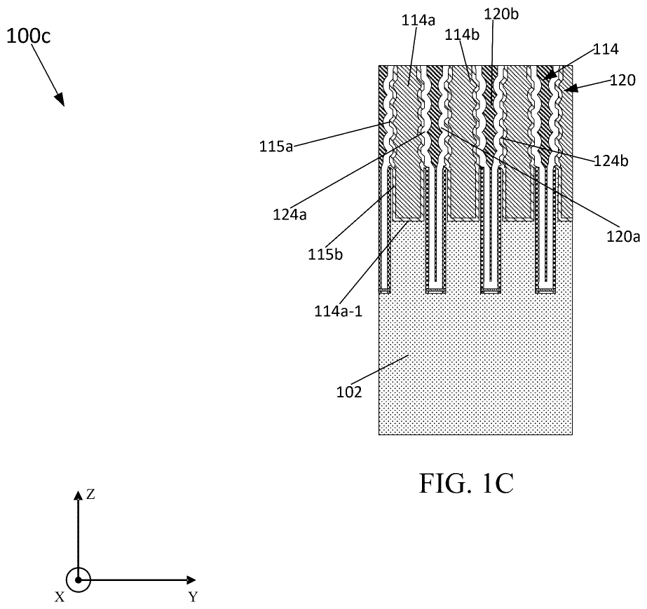

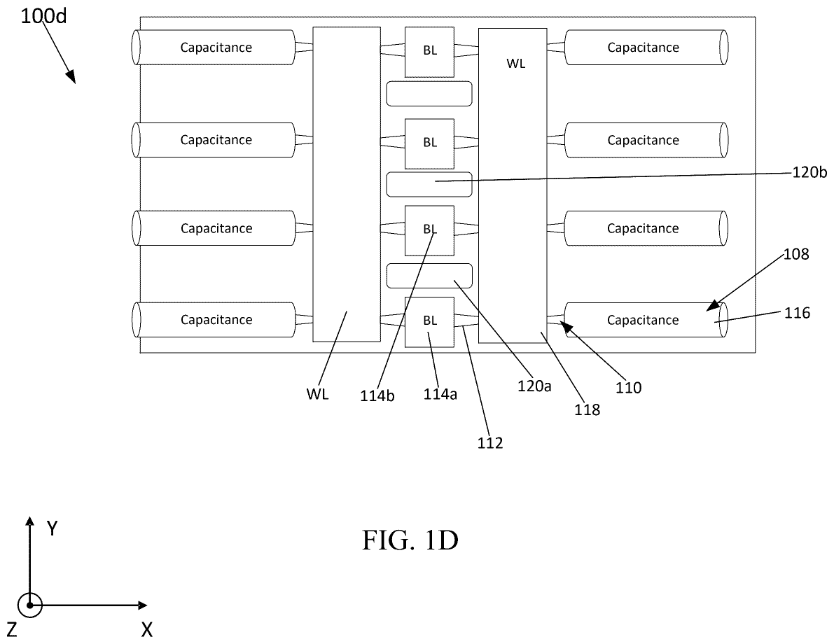

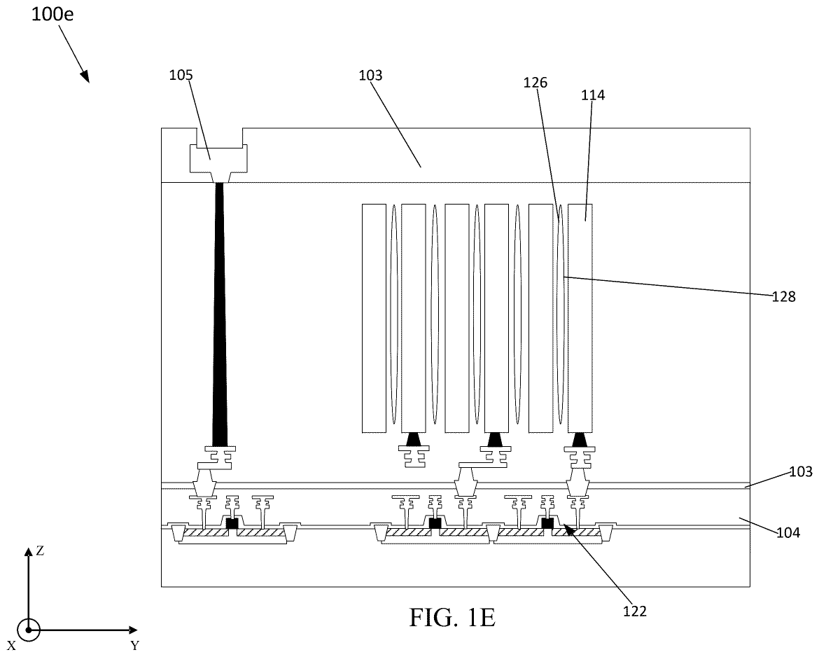

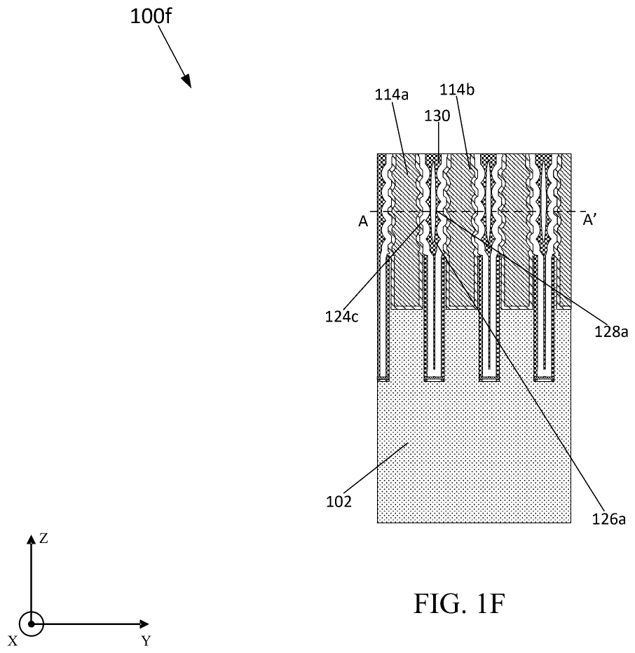

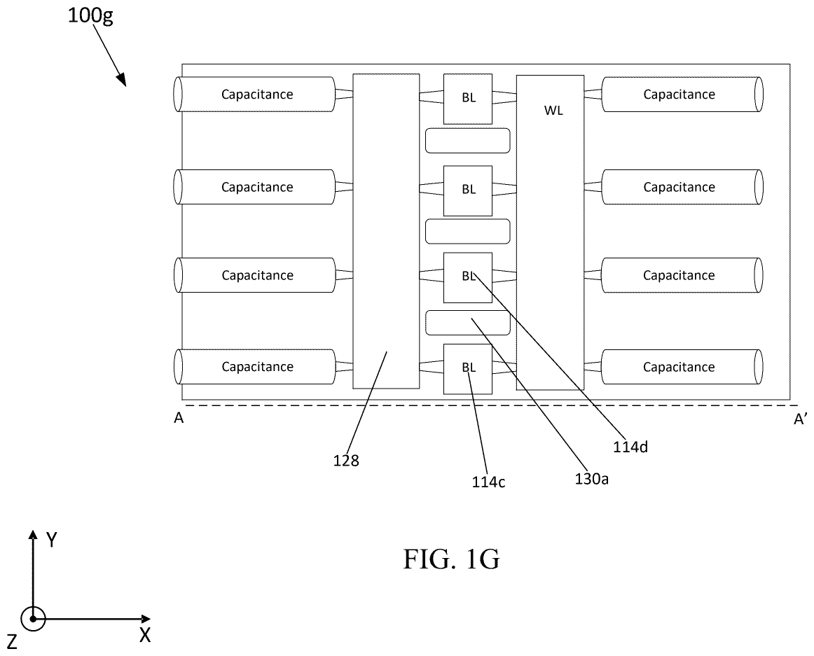

It is noted that X, Y, and Z axes (also referred to as X, Y, and Z directions) are included in FIGS. 1A-1E to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A is a perspective view of an example 3D semiconductor device 100a. It is understood that FIG. 1A is for illustrative purposes only and may not necessarily reflect the actual device structure (e.g., interconnections) in practice.

As shown in FIG. 1A, the semiconductor device 100a includes a semiconductor layer 102 and a CMOS layer 104. The semiconductor layer 102 is staked on the CMOS layer 104 along a vertical direction (e.g., the Z direction). In some implementations, the semiconductor device 100a also includes an array 106 of memory cells 108 stacked on the semiconductor layer 102 along the Z direction. The array 106 of the memory cells 108 includes columns 103 extending along the Z direction and rows 105 extending along a horizontal direction (e.g., the Y direction) perpendicular to the Z direction. In some implementations, as shown in FIG. 1A, the array 106 of the memory cells 108 are arranged in the Y direction, the Z direction, and a second horizontal direction (e.g., the X direction) perpendicular to the Y direction and the Z direction. In some implementations, the array 106 of the memory cells 108 can be a 3D dynamic random-access memory (DRAM). In some implementations, the CMOS layer 104 can include peripheral circuits such as interconnects and control circuits configured to control the array 106 of the memory cells 108. In some implementations, a memory cell 108 of the array 106 of the memory cells 108 includes a transistor 110 having a semiconductor body 112 extending along the X direction. In some implementations, the semiconductor layer 102 can be a substrate. In some implementations, semiconductor bodies 112 of the array 106 of the memory cells 108 can be formed by stacking on top of the substrate 102. In some implementations, the semiconductor bodies 112 of the array 106 of the memory cells 108 can include the same semiconductor material as the semiconductor layer 102. In some implementations, the semiconductor layer 102 can include semiconductor materials, such as single crystalline silicon, polysilicon, amorphous silicon, Ge, any other semiconductor materials, or any combinations thereof. In some implementations, the semiconductor bodies 112 can include semiconductor materials, such as single crystalline silicon, polysilicon, amorphous silicon, Ge, any other semiconductor materials, or any combinations thereof. In some implementations, the semiconductor layer 102 can be removed in later fabrication process.

The semiconductor body 112 of the transistor 110 has a first end 112-1 and a second end 112-2 on opposite sides of the semiconductor body 112 along the X direction. The first end 112-1 of the semiconductor body is in contact with a corresponding bit line 114 along the X direction. In some implementations, the second end 112-2 of the semiconductor body 112 is coupled to a storage structure 116 along the X direction. In some implementations, the storage structure 116 can be a capacitor that is used to store memory data of the memory cell 108. In some implementations, as shown in FIG. 1A, the storage structure 116 and the corresponding bit line 114 are connected by the transistor 110 along the X direction. In some implementations, the memory cell 108 further includes a gate structure 118 coupled to the semiconductor body 112. The gate structure 118 extends along the Y direction. In some implementations, the gate structure 118 can be shared by a plurality of memory cells 108 arranged along the Y direction. In some implementations, the gate structure 118 can be referred to as a word line. In some implementations, the array 106 of the memory cells 108 can include multiple gate structures 118 that are stacked on top of each other along the Z direction. In some implementations, (as shown in FIG. 1B), the peripheral circuits in the CMOS layer 104 are coupled to the gate structure 118 and the corresponding bit line 114. In some implementations, memory cells 108 of the array 106 can be arranged in rows extending along the Y direction and columns extending along the Z direction. In some implementations, the semiconductor device 100a can include a plurality of arrays 106 of the memory cells 108. The plurality of arrays 106 are mirrored to each other along the X direction. For example, as shown in FIG. 1A, two adjacent arrays 106 of the memory cells 108 are mirrored with respect to bit lines 114 along the X direction. In some implementations, the two adjacent arrays 106 of the memory cells 108 can share same bit lines 114 that are between the two adjacent arrays 106 of the memory cells 108. In some implementations, each of the two adjacent arrays 106 of the memory cells 108 can be coupled to separate bit lines 114 along the X direction. In another example (not shown in FIG. 1A), the semiconductor device 100a can include two arrays 106 of the memory cells 108 that are mirrored with respect to storage structures 116 along the X direction.

As shown in FIG. 1A, the semiconductor device 100a includes a plurality of bit lines 114, where a number of the plurality of bit lines 114 matches a number of columns in the array 106 of the memory cells 108. In some implementations, as shown in FIG. 1A, the plurality of bit lines 114 extend along the Z direction and are separated from each other along the Y direction. In some implementations, the plurality of bit lines 114 are in contact with the semiconductor layer 102 along the Z direction. In some implementations, the semiconductor device 100a further includes conductive structures 120 extending along the Z direction. The bit lines 114 and the conductive structures 120 are alternately arranged along the Y direction. In some implementations, the bit lines 114 and the conductive structures 120 are isolated by a dielectric material (e.g., SiO2) along the Y direction.

FIG. 1B illustrates a cross-section view of the example semiconductor device 100b. The semiconductor device 100b can be a cross-sectional view of the semiconductor device 100a that is cut along the X axis.

As shown in FIG. 1B, a bonding layer 103 is between the CMOS layer 104 and the array 106 of the memory cells 108 along the Z direction. In some implementations, the bonding layer is used to connect the array 106 of the memory cells 108 and the CMOS layer 104. The bonding layer 103 can include a top bonding layer and a bottom bonding layer bonded at a bonding interface. Each of the top bonding layer and the bottom bonding layer can include a dielectric material (including, but not limited to, silicon oxide, silicon nitride, silicon oxynitride, low-k dielectrics, or any combination thereof) and can exclude a conductive bonding contact. The array 106 of the memory cells 108 can be bonded on top of the CMOS layer 104 in a face-to-face manner through the bonding layer 103. A bonding interface is disposed between the top bonding layer and the bottom bonding layer as a result of direct bonding (e.g., dielectric-dielectric bonding), which forms bonding between surfaces without using intermediate layers, such as solder or adhesives. In some implementations (not shown in FIG. 1B), for example, when the dielectric material of the top bonding layer and the dielectric material of the bottom bonding layer are different materials, the bonding interface can be a visible layer with a certain thickness that includes a top surface of the bottom bonding layer and a bottom surface of the top bonding layer. In some implementations, as shown in the example of FIG. 1B, when the dielectric material of the top bonding layer and the dielectric material of the bottom bonding layer are the same material, the bonding interface may not be visible, and the top bonding layer and the bottom bonding layer may form a continuous bonding layer 103.

The CMOS layer 104 includes peripheral circuits 122 such as interconnects and control circuits that are configured to control the array 106 of the memory cells 108. As shown in FIG. 1B, the memory cells 108 of the array 106 are stacked on top of each other along the Z direction and are connected to the bit line 114 along the X direction. The bit line 114 extends along the Z direction and is coupled to the peripheral circuits 122 through the interconnects along the Z direction. In some implementations, the peripheral circuits 122 further include a voltage controller coupled to conductive structures 120, where the voltage controller is configured to supply a fixed voltage to the conductive structures 120.

In some implementations, the semiconductor device 100b can include a dielectric layer 103 stacked on the array 106 of the memory cells 108. The dielectric layer 103 can include a coupling out structure 105. In some implementations, the coupling out structure 105 is connected to the peripheral circuits 122 of the CMOS layer 104 and can be used to connect with a memory controller that is configured to control the array 106 of the memory cells 108.

FIG. 1C illustrates a cross-section view of the example semiconductor device 100c. The semiconductor device 100c can be a cross-sectional view of the semiconductor device 100a that is cut along the Y axis.

As shown in FIG. 1C, the semiconductor device 100c includes bit lines 114 and conductive structures 120 extending along the Z direction. The bit lines 114 and the conductive structures 120 are alternately arranged along the Y direction. In some implementations, the bit lines 114 and the conductive structures 120 are isolated by a dielectric material along the Y direction.

In some implementations, the conductive structures 120 are connected together. In some implementations, the conductive structures 120 are configured to be coupled to a fixed voltage equal to or smaller than a ground voltage. In some implementations, the conductive structures 120 can be used as metal shields for the bit lines 114. The metal shields are configured to electrically isolate the bit lines 114 from each other and reduce the coupling effect between the bit lines 114. The reduction of the coupling effect between the bit lines 114 can also help to improve the sense margin of the semiconductor device 100c during operation.

As shown in FIG. 1C, the semiconductor device 100c further includes a semiconductor layer 102 extending along a plane perpendicular to the Z direction. In some implementations, the bit lines 114 are in contact with the semiconductor layer 102 along the Z direction, and the conductive structures 120 extend into the semiconductor layer 102 along the Z direction. In some implementations (as shown in FIG. 1B), the semiconductor layer 102 can be used as a bonding layer that bonds the semiconductor device 100c to a CMOS layer (e.g., the CMOS layer 104 as shown in FIG. 1B).

In some implementations, the bit lines 114 include at least a first bit line 114a and a second bit line 114b extending along the Z direction. The conductive structures 120 include at least a first conductive structure 120a and a second conductive structure 120b extending along the Z direction. In some implementations, the first bit line 114a, the second bit line 114b, the first conductive structure 120a, and the second conductive structure 120b are alternately arranged along the Y direction. For example, as shown in FIG. 1C, the first conductive structure 120a is between the first bit line 114a and the second bit line 114b along the Y direction. In some implementations, first conductive structure 120a is separated from the first bit line 114a and the second bit line 114b by a first isolation layer 124a along the Y direction, and the second conductive structure 120b is separated from the second bit line 114b by a second isolation layer 124b. In some implementations, the first isolation layer 124a and the second isolation layer 124b can include a dielectric material such as SiO₂. It is understood that FIG. 1C is for illustration propose only, and the semiconductor device 100c can include different number of the bit lines 114 and the conductive structures 120 arranged alternatively along the Y direction.

In some implementations, the first conductive structure 120a extends beyond at least one end 114a-1 of the first bit line 114a along the Z direction. In some implementations, the first bit line 114a includes a wave portion 115a and a straight portion 115b along the Z direction. In some implementations, the conductive structure 120a can include a conductive material such as metal or metal silicide including, but not limited W, Co, Cu, Al, TiN, TaN, WSi, CoSi, CuSi, AlSi, or any combination thereof.

FIG. 1D illustrates a top view of the example semiconductor device 100d. The semiconductor device 100d can be a top view of the semiconductor device 100a along a plane perpendicular to the Z direction.

As shown in FIG. 1D, the first bit line 114a is connected to at least one memory cell 108 having a transistor 110 and a storage structure 116. The storage structures 116 and the first bit line 114a are connected by a semiconductor body 112 of the transistor 110 along the X direction. In some implementations, the memory cell 108 includes a gate structure 118 that is coupled to the semiconductor body 112 of the transistor 110. In some implementations, the semiconductor device 100d includes a row of memory cells 108 arranged along the Y direction, and the gate structure 118 extends along the Y direction coupled to the row of the memory cells 108. In some implementations, the gate structure 118 can be referred to as a word line of the row of the memory cells 108. In some implementations, a cross section of the first conductive structure 120a and the second conductive structure 120b perpendicular to the Z direction have a rectangular shape or ellipse shape. In some implementations, as shown in FIG. 1D, a width of the first conductive structure 120a along the X direction is greater than a width of the first bit line 114a along the X direction. The greater width of the first conductive structure 120a ensures the first bit line 114a can be fully shielded by the first conductive structure 120a to reduce the coupling effect and improve the sense margin.

FIG. 1E illustrates a cross-section view of the example semiconductor device 100e. The semiconductor device 100e can be a cross-sectional view of the semiconductor device 100a that is cut along the Y axis. The semiconductor device 100e can be similar to the semiconductor device 100c except the conductive structures 120 of the semiconductor device 100c are replaced by isolation structures in the semiconductor device 100e.

The semiconductor device 100e includes bit lines 114 and isolation structures 126 extending along the Z direction. The bit lines 114 and the isolation structures 126 alternate with one another along the Y direction. In some implementations, the bit lines 114 and the isolation structures 126 are isolated by a dielectric material along the Y direction. In some implementations, as shown in FIG. 1E, each of the isolation structures 126 can include an airgap 128. In some implementations (not shown in FIG. 1E), each of the isolation structures 126 can include a dielectric material with a low dielectric permittivity. For example, a dielectric permittivity of the dielectric material in the isolation structure 126 is in a range between 1 and 4.

In some implementations, the airgap 128 in each of the isolation structures 126 can be used to reduce a capacitance between two adjacent bit lines 114 along the Y direction. The reduction of the capacitance between the two adjacent bit lines 114 can reduce a coupling effect between the two adjacent bit lines 114 and improve the sense margin of memory cells of the semiconductor device 100e.

FIG. 1F illustrates a cross-section view of the example semiconductor device 100f. The semiconductor device 100f can be a cross-sectional view of the semiconductor device 100a that is cut along the Y axis. The semiconductor device 100f can be similar to the semiconductor device 100e of FIG. 1E.

As shown in FIG. 1F, the bit lines 114 can include at least a third bit line 114c and a fourth bit line 114d. The isolation structures 126 can include at least a first isolation structure 126a. In some implementations, the first isolation structure 126a is between the third bit line 114c and the fourth bit line 114d along the Y direction. The first isolation structure 126a is separated from the third bit line 114c and the fourth bit line 114d by a third isolation layer 124c along the Y direction. In some implementations, the first isolation structure 126a includes a first airgap 128a. The first airgap 128a is surrounded by a dielectric outer layer 130.

In some implementations, the semiconductor device 100f includes the semiconductor layer 102 in a plane perpendicular to the Z direction. As shown in FIG. 1F, the third bit line 114c and the fourth bit line 114d are in contact with the semiconductor layer 102 along the Z direction. The first isolation structure 126a extends into the semiconductor layer 102 along the Z direction. In some implementations (not shown in FIG. 1F), the first airgap 128a of the first isolation structure 126a can be replaced by a low-k dielectric material with a relative permittivity in a range between 1 and 4. In some implementations (not shown in FIG. 1F), the first airgap 128a of the first isolation structure 126a can be replaced by a conductive material, where the conductive material is coupled to a fixed voltage equal to or smaller than a ground voltage.

FIG. 1G illustrates a top view of the example semiconductor device 100g along cut line AA′ of the semiconductor device 100f of FIG. 1F. As shown in FIG. 1G, a cross section of the first airgap 130a perpendicular to the Z direction have a rectangular shape or ellipse shape. In some implementations, as shown in FIG. 1G, a width of the first airgap 130a along the X direction is greater than a width of the third bit line 114c along the X direction. The greater width of the first airgap 130a ensures the third bit line 114c can be fully isolated from the fourth bit line 114d along the Y direction to reduce the capacitance between the third bit line 114c and the fourth bit line 114d.

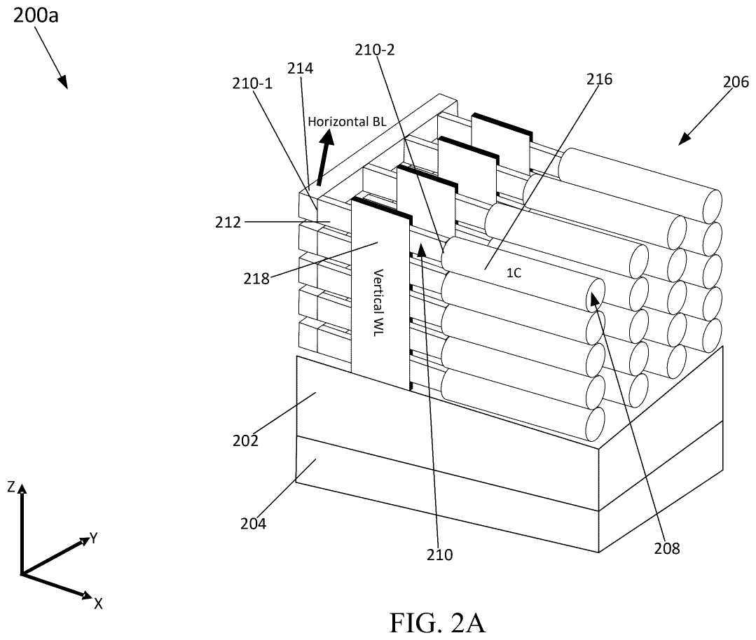

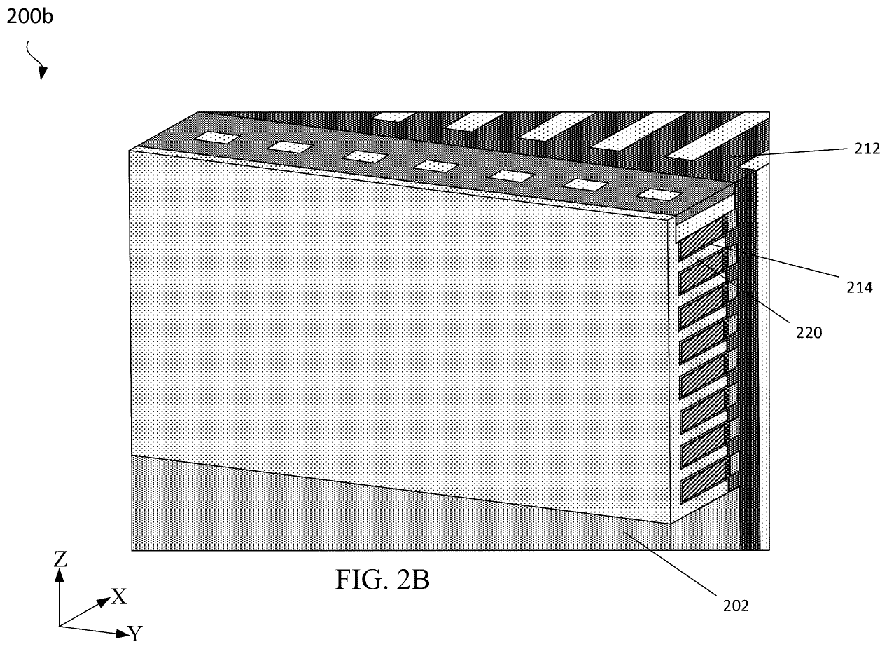

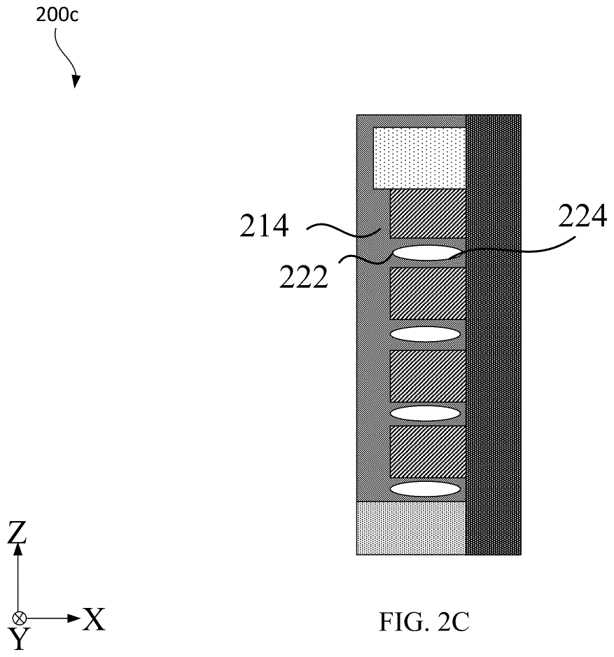

FIG. 2A is a perspective view of an example 3D semiconductor device 200a. The semiconductor device 200a can be similar to the semiconductor device 100a of FIG. 1A except memory cells and bit lines of the semiconductor device 200a have different arrangements compared to the semiconductor device 100a.

As shown in FIG. 2A, the semiconductor device 200a includes a semiconductor layer 202 and a CMOS layer 204. The semiconductor layer 202 is staked on the CMOS layer 204 along a vertical direction (e.g., the Z direction). In some implementations, the semiconductor device 200a also includes an array 206 of memory cells 207 stacked on the semiconductor layer 202 along the Z direction. In some implementations, the array 206 of the memory cells 207 can be a 3D dynamic random-access memory (DRAM). The array 206 of the memory cells 207 includes columns 203 extending along the Z direction and rows 205 extending along a horizontal direction (e.g., the Y direction) perpendicular to the Z direction. In some implementations, the CMOS layer 204 can include peripheral circuits such as interconnects and control circuits configured to control the array 206 of the memory cells. In some implementations, a memory cell 207 of the array 206 of the memory cells 207 includes a transistor 210 having a semiconductor body 212 extending along a second horizontal direction (e.g., the X direction) perpendicular to the Y direction and the Z direction. In some implementations, semiconductor bodies 212 of the array 206 of the memory cells 207 can be formed by stacking on top of the semiconductor layer 202. In some implementations, the semiconductor layer 207 can be removed in later fabrication process.

The semiconductor body 212 of the transistor 210 has a first end 212-1 and a second end 212-2 on opposite sides of the semiconductor body 212 along the X direction. The first end 212-1 of the semiconductor body is in contact with a corresponding bit line 214 along the X direction. In some implementations, the second end 212-2 of the semiconductor body 212 is coupled to a storage structure 216 along the X direction. In some implementations, the storage structure 216 can be a capacitor that is used to store memory data of the memory cell 207. In some implementations, as shown in FIG. 2A, the storage structure 216 and the corresponding bit line 214 are connected by the transistor 210 along the X direction. In some implementations, the memory cell 207 further includes a gate structure 218 coupled to the semiconductor body 212. The gate structure 218 extends along the Z direction. In some implementations, the gate structure 218 can be shared by a plurality of memory cells 108 arranged along the Z direction. In some implementations, the gate structure 118 can be referred to as a word line. In some implementations, the gate structure 218 is in contact with the semiconductor layer 202. In some implementations, the peripheral circuits in the CMOS layer 204 are coupled to the gate structure 218 and the corresponding bit line 214. In some implementations, memory cells 208 of the array 206 can be arranged in rows extending along the Y direction and columns extending along the Z direction. As shown in FIG. 2A, each of the rows of the memory cells 108 are coupled to a corresponding bit line 214. The semiconductor device 200a includes a plurality of bit lines 214, where a number of the plurality of bit lines 214 matches a number of rows in the array 206 of the memory cells 208. In some implementations, as shown in FIG. 2A, the plurality of bit lines 214 are stacked on top of each other along the Z direction. In some implementations, the semiconductor device 200a can include a plurality of arrays 206 of the memory cells 208. The plurality of arrays 206 are mirrored to each other along the X direction. For example, two adjacent arrays 206 of the memory cells 208 are mirrored with respect to bit lines 214 along the X direction. In another example, the semiconductor device 200a can include two arrays 206 of the memory cells 208 that are mirrored with respect to storage structures 116 along the X direction.

FIG. 2B is a perspective view of an example semiconductor device 200b. The semiconductor device 200b can be a portion of the semiconductor device 200a of FIG. 2A. The semiconductor device 200b can be similar to the semiconductor device 100c of FIG. 1C except memory cells and bit lines of the semiconductor device 200b have different arrangements compared to the semiconductor device 100c.

As shown in FIG. 2B, the semiconductor device 200b includes conductive structures 220. The conductive structures 220 extend along the Y direction. In some implementations, as shown in FIG. 2B, the bit lines 214 and the conductive structures 220 are alternately arranged along the Z direction. In some implementations, the conductive structures 220 are connected together and coupled to a fixed voltage equal to or smaller than a ground voltage. In some implementations, the conductive structures 220 can be used as metal shields for the bit lines 214 to electrically isolate the bit lines 214 from each other along the Z direction. The metal shields can be used to reduce the coupling effect between two adjacent bit lines and improve the sense margin of memory devices.

FIG. 2C is a cross-sectional view of an example semiconductor device 200c. The semiconductor device 200c can be similar to the semiconductor device 200b of FIG. 2B except the conductive structures 220 of the semiconductor device 200b are replaced by isolation structures in the semiconductor device 200c.

As shown in FIG. 2C, the semiconductor device 200c includes isolation structures 222 that extend along the Y direction. The isolation structures 222 and the bit lines 214 are alternately arranged along the Z direction. In some implementations, as shown in FIG. 2C, each of the isolation structures 222 includes an airgap 224. The airgap 224 in each of the isolation structures 222 can be used to reduce a capacitance between two adjacent bit lines 214. The reduce of the capacitance can be used to reduce the coupling effect and improve sense margin of the two adjacent bit lines 214. In some implementations (not shown in FIG. 2C), the airgap 224 in each of the isolation structures 222 can be replaced by a low-k dielectric material with a relative permittivity in a range between 1 and 4.

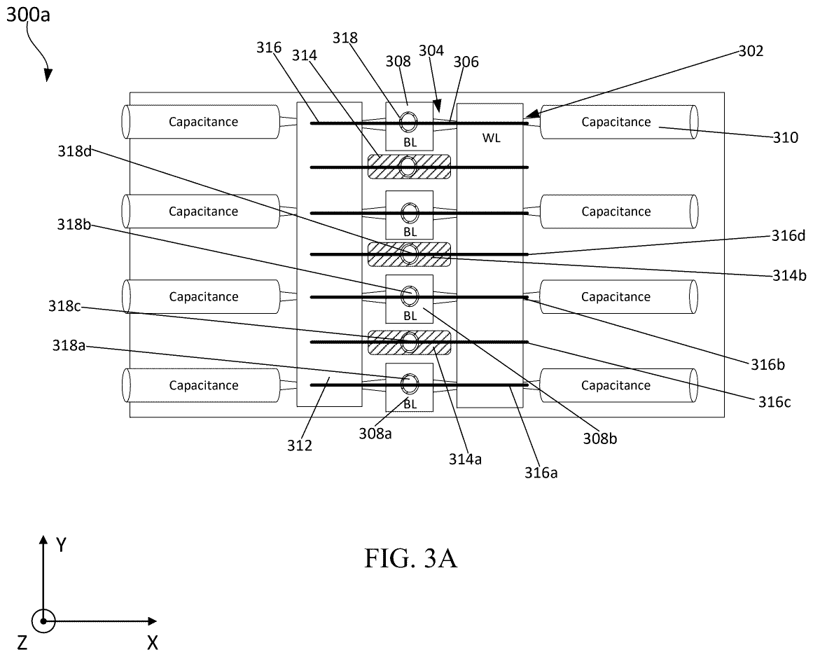

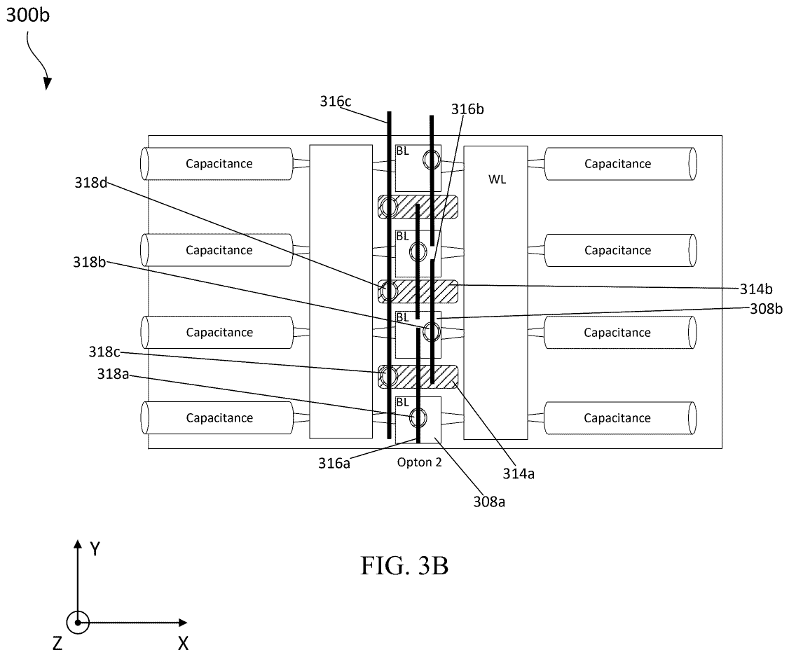

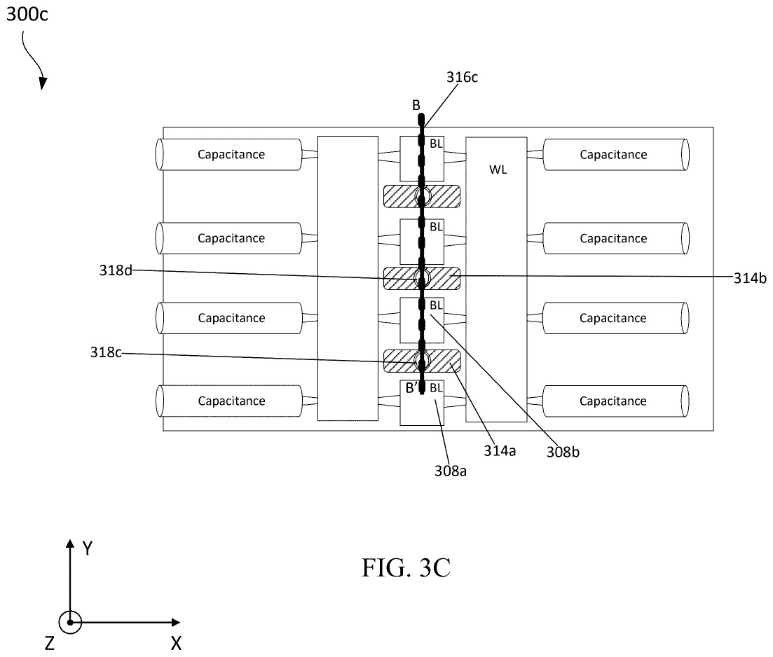

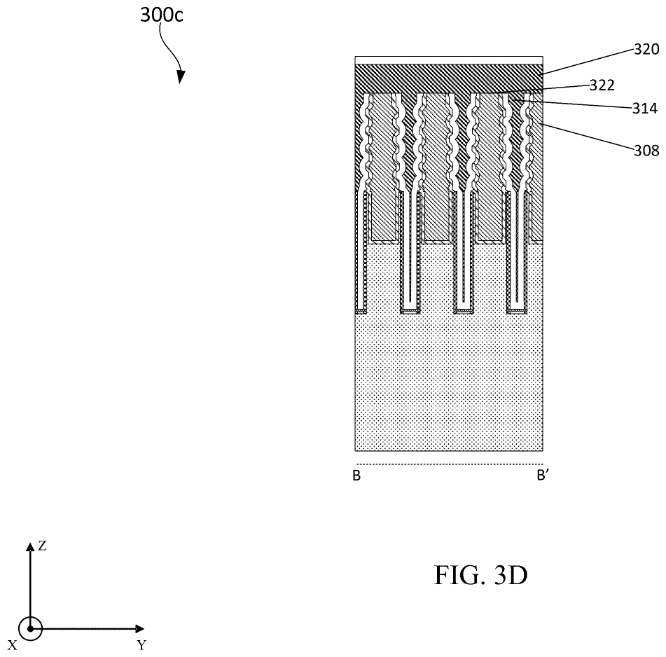

FIG. 3A illustrates a top view of an example semiconductor device 300a. The semiconductor device 300a can be similar to, or same as the semiconductor device 100d of FIG. 1D.

As shown in FIG. 3A, the semiconductor device 300a includes memory cells 302. Each of the memory cells 302 includes a transistor 304 having a semiconductor body 306 extending along the X direction. The semiconductor device 300a also includes bit lines 308 extending along the Z direction and storage structures 310. In some implementations, each of the transistor of a corresponding memory cell 302 is connected to a corresponding bit line 308 and a corresponding storage structure 310 along the X direction by the semiconductor body. In some implementations, as shown in FIG. 3A, the semiconductor device 300a also includes word lines 312 extending along the Y direction. Each of the word lines 312 is coupled to corresponding memory cells arranged along the Y direction.

The semiconductor device 300a includes conductive structures 314 extending along the Z direction. As shown in FIG. 3A, the conductive structures 314 and the bit lines are alternately arranged along the Y direction. In some implementations, each of the conductive structures 314 and each of the bit lines 308 are coupled to one or more wires 316 through a corresponding contact 318. In some implementations, the conductive structures 314 includes at least a first conductive structure 314a and a second conductive structure 314b. The first conductive structure 314a and the second conductive structure 314b are connected to one or more wires 316 through respective contacts 318.

For example, as shown in FIG. 3A, the bit lines 308 include at least a first bit line 308a and a second bit line 308b. As shown in FIG. 3A, the first bit line 308a is connected to a first wire 316a through a first contact 318a, the second bit line 308b is connected to a second wire 316b through a second contact 318b. The first conductive structure 314a is connected to a third wire 316c through a third contact 318c, and the second conductive structure 314b is connected to a fourth wire 316d through a fourth contact 318d. In some implementations, the conductive structures 314 are coupled together by connecting the wires coupled to corresponding conductive structures. For example, the first conductive structure 314a and the second conductive are connected together by connecting the third wire 316c and the fourth wire 316d. In some implementations, as shown in FIG. 3A, the first wire 316a, the second wire 316b, the third wire 316c, and the fourth wire 316d are extending along the X direction, located on a same side of the bit lines 308, and are separated from one another.

FIG. 3B illustrates a top view of an example semiconductor device 300b. The semiconductor device 300b can be similar to the semiconductor device 300a of FIG. 3A except that the wires of the semiconductor device 300b have different arrangements compared to the semiconductor device 300a.

The semiconductor device 300b includes a fifth wire 316e, a sixth wire 316f and a seventh wire 316g. As shown in FIG. 3B, the first conductive structure 314a is connected to the fifth wire 316e through a fifth contact 318e, and the second conductive structure 314b is connected to the fifth wire 316e through a sixth contact 318f. The first bit line 308a is connected to the sixth wire 316f through a seventh contact 318g, and the second bit line 308b is connected to the seventh wire 316g through an eighth contact 318h. In some implementations, the fifth wire 316e, the sixth wire 316f and the seventh wire 316g are located on a same side of the bit lines 308, extend along the Y direction, and are separated from one another.

FIG. 3C illustrates a top view of an example semiconductor device 300c. The semiconductor device 300c can be similar to the semiconductor device 300a of FIG. 3A except that the wires of the semiconductor device 300c have different arrangements compared to the semiconductor device 300a.

The semiconductor device 300c includes an eighth wire 316h. As shown in FIG. 3C, the first conductive structure 314a is connected to the eighth wire 316h through a ninth contact 318i, and the second conductive structure 314b is connected to the eighth wire 316h through a tenth contact 318j. The eighth wire 316h extends along the Y direction. In some implementations, the first wire 316a and the second wire 316b are located on a same side of the bit lines 308, where the first wire 316a and the eighth wire 316h are on opposite sides of the bit lines 308 along the Z direction.

FIG. 3D illustrates a cross-sectional view of the semiconductor device 300c along cut line BB′ of FIG. 3C. As shown in FIG. 3D, the conductive structures 314 are connected together to an interconnect structure 320 along the Z direction. The interconnect structure 320 extends along the Y direction. In some implementations, the interconnect structure 320 and the conductive structures 314 form a continuous structure. In some implementations, the interconnect structure 320 can be similar to, or same as an integrated body of the eighth wire 316h and corresponding contacts (e.g., the ninth contact 318i and the tenth contact 318j of FIG. 3C) of the semiconductor device 300c of FIG. 3C. In some implementations, as shown in FIG. 3D, the bit lines 308 are separated from the interconnect structure 320 by a dielectric layer 322.

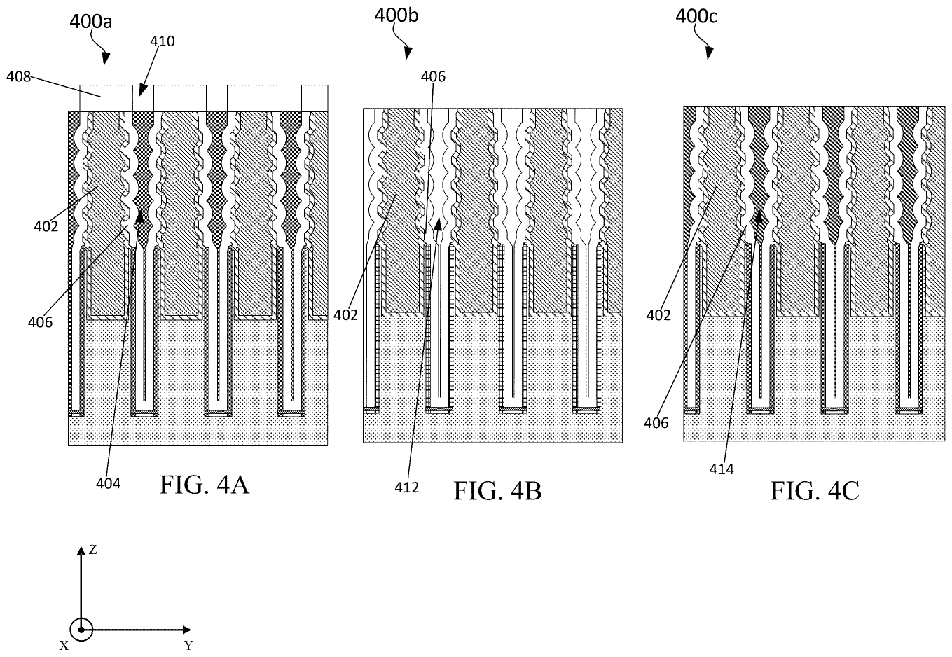

FIG. 4A-4C illustrate an example process of fabricating a semiconductor device, such as the semiconductor device 100c as illustrated in FIG. 1C. FIG. 4A-4C show cross-sectional views of example semiconductor structures at various stages of the fabrication process.

FIG. 4A illustrates a semiconductor structure 400a. The semiconductor structure 400a includes bit lines 402 extending along a vertical direction (e.g., the Z direction). The bit lines are separated by sacrificial structures 404 along a horizontal direction (e.g., the Y direction) perpendicular to the Z direction. The sacrificial structures 404 include a first sacrificial material (e.g., poly-Si or C) surrounded by a dielectric layer 406. The semiconductor structure 400a also includes a sacrificial layer 408, which can be formed by depositing a second sacrificial material (e.g., photoresist) on top of the bit lines 402 and the sacrificial structures 404. The semiconductor structure 400a also includes first trenches 410, which can be formed by etching a portion of the sacrificial layer 408 along the Z direction. The first trenches 410 are in contact with the first sacrificial material of the sacrificial structures 404.

FIG. 4B illustrates a semiconductor structure 400b, which can be formed by filling an etch solution into the first trenches 410 to etch the first sacrificial material of the sacrificial structures 404 to form second trenches 412. The sacrificial layer 408 is used to protect the bit lines 402 from the etching process which is removed after the forming of the second trenches 412.

FIG. 4C illustrates a semiconductor structure 400c, which can be formed by depositing a conductive material into the second trenches to form conductive structures 414. As shown in FIG. 4C, the conductive structures 414 are separated from the bit lines 402 by the dielectric layer 406.

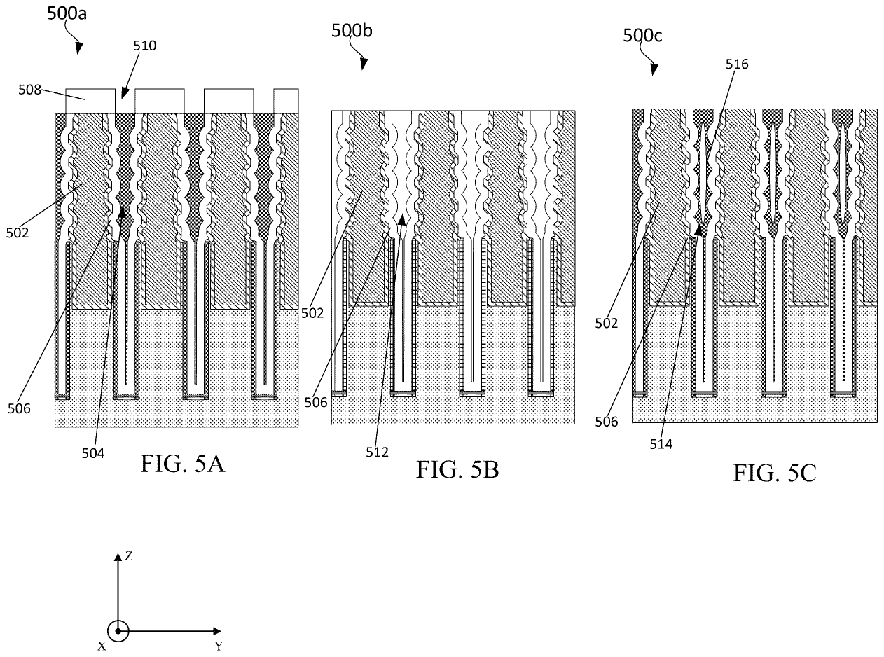

FIG. 5A-5C illustrate an example process of fabricating a semiconductor device, such as the semiconductor device 100f as illustrated in FIG. 1F. FIG. 5A-5C show cross-sectional views of example semiconductor structures at various stages of the fabrication process.

FIG. 5A illustrates a semiconductor structure 500a. The semiconductor structure 500a includes bit lines 502 extending along a vertical direction (e.g., the Z direction). The bit lines are separated by sacrificial structures 504 along a horizontal direction (e.g., the Y direction) perpendicular to the Z direction. The sacrificial structures 504 include a first sacrificial material (e.g., poly-Si or C) surrounded by a dielectric layer 506. The semiconductor structure 500a also includes a sacrificial layer 508, which can be formed by depositing a second sacrificial material (e.g., photoresist) on top of the bit lines 502 and the sacrificial structures 504. The semiconductor structure 500a also includes first trenches 510, which can be formed by etching a portion of the sacrificial layer 508 along the Z direction. The first trenches 510 are in contact with the first sacrificial material of the sacrificial structures 504.

FIG. 5B illustrates a semiconductor structure 500b, which can be formed by filling an etch solution into the first trenches 510 to etch the first sacrificial material of the sacrificial structures 504 to form second trenches 512. The sacrificial layer 508 is used to protect the bit lines 502 from the etching process which is removed after the forming of the second trenches 512.

FIG. 5C illustrates a semiconductor structure 500c, which can be formed by depositing a low-k dielectric material into the second trenches at a high depositing rate to form isolation structures 514. As a result of the high depositing rate, airgaps 516 are formed in the middle of the isolation structures 514 after the deposition process.

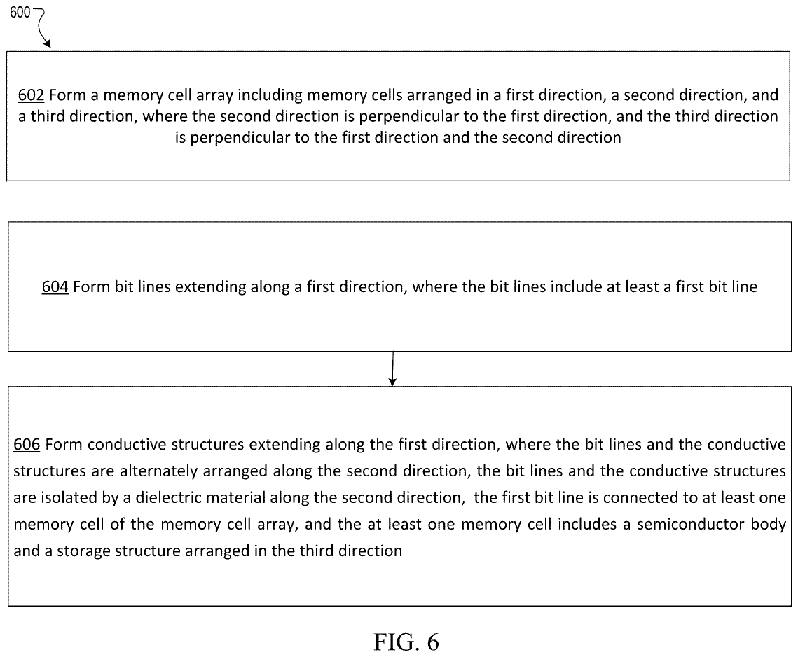

FIG. 6 illustrates a flow chart of an example process 600. The process 600 can be performed to form a semiconductor device (e.g., the semiconductor device 100c illustrated by FIG. 1C or the semiconductor device 100f illustrated by FIG. 1F). The process 600 can be described in view of FIG. 4A-4C or FIG. 5A-5C. The process 600 can include one or more steps of the fabrication process of forming the semiconductor structures in FIG. 4A-4C or FIG. 5A-5C. It is understood that the operations shown in process 600 are not exhaustive and that other operations can be performed as well before, after, or between any of the illustrated operations. Further, some of the operations may be performed simultaneously, or in a different order than shown in FIG. 6.

At operation 602, a memory cell array (e.g., the memory cell array 106 of FIG. 1A) including memory cells (e.g., the memory cells 108 of FIG. 1A) arranged in a first direction (e.g., the Z direction), a second direction (e.g., the Y direction), and a third direction (e.g., the X direction) is formed, where the second direction is perpendicular to the first direction, and the third direction is perpendicular to the first direction and the second direction

At operation 604, bit lines (e.g., the bit lines 114 of FIG. 1C) extending along the first are formed, the bit lines include at least a first bit line (e.g., the fit bit line 114a of FIG. 1C).

At operation 606, conductive structures (e.g., the conductive structures 120 of FIG. 1C) extending along the first direction are formed, where the bit lines and the conductive structures are alternately arranged along the second direction, where the bit lines and the conductive structures are isolated by a dielectric material along the second direction; the first bit line is connected to at least one memory cell (e.g., the at least one memory cell 108 of FIG. 1D) of the memory cell array; and the at least one memory cell includes a semiconductor body and a storage structure arranged in the third direction.

In some implementations, forming the conductive structures includes providing a semi-conductor structure (e.g., the semiconductor structure 400a of FIG. 4A) having the bit lines extending along the first direction, where the bit lines are separated by sacrificial structures (e.g., the sacrificial structures 404 of FIG. 4A) along the second direction, and where the sacrificial structures include a sacrificial material surrounded by a dielectric layer (e.g., the dielectric layer 406 of FIG. 4A); removing the sacrificial material in the sacrificial structures by an etching process to form first trenches (e.g., the second trenches 412 of FIG. 4B); and filling a conductive material into the first trenches to form the conductive structures.

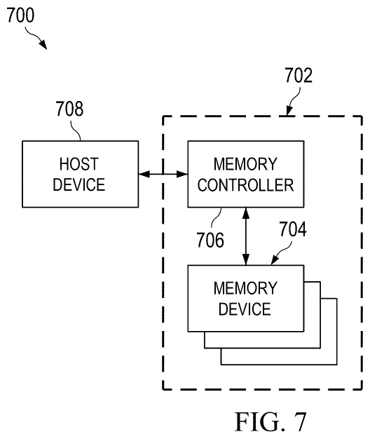

FIG. 7 illustrates a block diagram of a system 700 having one or more semiconductor devices (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, the system 700 can include a host device 708 and a memory system 702 having one or more 3D memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more 3D memory devices 704.

A 3D memory device 704 can be any 3D memory device disclosed herein, such as a 3D memory device depicted in FIG. 1A-1G or FIG. 2A-2C. In some implementations, a 3D memory device 704 includes a DRAM memory. Memory controller 706 (a.k.a., a controller cir-cuit) is coupled to 3D memory device 704 and host device 708. Consistent with implementations of the present disclosure, 3D memory device 704 can include a plurality of conductive interconnections through a cover layer that ar1e in contact with conductive pads in a conductive pad layer, and memory controller 706 can be coupled to 3D memory device 704 through at least one of the plurality of conductive interconnections. Memory controller 706 is configured to control 3D memory device 704. For example, memory controller 706 may be configured to operate a plurality of channel structures via word lines. Memory controller 706 can manage data stored in 3D memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, lap-top computers, etc., and enterprise storage arrays. Memory controller 706 can be configured to control operations of 3D memory device 704, such as read, erase, and program (or write) operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more 3D memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 7, memory controller 706 and a single 3D memory device 704 may be integrated into a memory card 702. Memory card 702 can include a PC card (PCMCIA, personal computer memory card international association), a CF card, a smart media (SM) card, a memory stick, a multi-media card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a memory cell array comprising memory cells arranged in a first direction, a second direction, and a third direction, wherein the second direction is perpendicular to the first direction, and the third direction is perpendicular to the first direction and the second direction;
bit lines extending along the first direction, wherein the bit lines comprise at least a first bit line; and
conductive structures extending along the first direction, wherein the bit lines and the conductive structures are alternately arranged along the second direction, and wherein:
the bit lines and the conductive structures are isolated by a dielectric material along the second direction;
the first bit line is connected to at least one memory cell of the memory cell array; and
the at least one memory cell comprises a semiconductor body and a storage structure arranged in the third direction.

2. The semiconductor device of claim 1, wherein the conductive structures are connected together.

3. The semiconductor device of claim 1, wherein the conductive structures are configured to be coupled to a fixed voltage equal to or smaller than a ground voltage.

4. The semiconductor device of claim 1, wherein the first bit line comprises a wave portion and a straight portion along the first direction.

5. The semiconductor device of claim 1, wherein the semiconductor device further comprises a semiconductor layer extending along a plane perpendicular to the first direction, wherein the bit lines are in contact with the semiconductor layer along the first direction, and wherein the conductive structures extend into the semiconductor layer along the first direction.

6. The semiconductor device of claim 5, wherein:
the bit lines further comprise a second bit line;
the conductive structures comprise at least a first conductive structure and a second conductive structure; and
the first conductive structure is adjacent to the first bit line along the second direction.

7. The semiconductor device of claim 6, wherein the first conductive structure extends beyond at least one end of the first bit line along the first direction.

8. The semiconductor device of claim 6, wherein a width of the first conductive structure along the third direction is greater than a width of the first bit line along the third direction.

9. The semiconductor device of claim 6, wherein a cross section of the first conductive structure perpendicular to the first direction has a rectangular shape or an ellipse shape.

10. The semiconductor device of claim 6, wherein the first conductive structure and the second conductive structure are connected to an interconnect structure along the first direction, wherein the interconnect structure extends along the second direction.

11. The semiconductor device of claim 6, wherein the first conductive structure and the second conductive structure are connected to one or more wires through respective contacts.

12. The semiconductor device of claim 11, wherein the first bit line is connected to a first wire through a first contact, the second bit line is connected to a second wire through a second contact.

13. The semiconductor device of claim 12, wherein the first conductive structure is connected to a third wire through a third contact, the second conductive structure is connected to a fourth wire through a fourth contact, the first wire, the second wire, the third wire, and the fourth wire are located on a same side of the bit lines, extend along the third direction, and are separated from one another.

14. The semiconductor device of claim 12, wherein the first conductive structure is connected to a third wire through a third contact, the second conductive structure is connected to the third wire through a fourth contact, the first wire, the second wire, and the third wire are located on a same side of the bit lines, extend along the second direction, and are separated from one another.

15. The semiconductor device of claim 12, wherein the first conductive structure is connected to a third wire through a third contact, the second conductive structure is connected to the third wire through a fourth contact, the third wire extends along the second direction, the first wire and the second wire are located on a same side of the bit lines, the first wire and the third wire are on opposite sides of the bit lines.

16. A semiconductor device, comprising:
bit lines extending along a first direction;
isolation structures extending along the first direction; and
a semiconductor layer extending in a plane perpendicular to the first direction, wherein:
the bit lines are in contact with the semiconductor layer along the first direction;
the bit lines and the isolation structures are arranged in a line extending along a second direction perpendicular to the first direction;
the bit lines and the isolation structures alternate with one another along the second direction; and
the bit lines and the isolation structures are isolated by a dielectric material along the second direction.

17. The semiconductor device of claim 16, wherein the at least one of the isolation structures comprises a conductive structure.

18. The semiconductor device of claim 16, wherein the at least one of the isolation structures comprises an airgap.

19. A method of forming a semiconductor device, comprising:
forming a memory cell array comprising memory cells arranged in a first direction, a second direction, and a third direction, wherein the second direction is perpendicular to the first direction, and the third direction is perpendicular to the first direction and the second direction;
forming bit lines extending along the first direction, wherein the bit lines comprise at least a first bit line; and
forming conductive structures extending along the first direction, wherein the bit lines and the conductive structures are alternately arranged along the second direction, and wherein:
the bit lines and the conductive structures are isolated by a dielectric material along the second direction;
the first bit line is connected to at least one memory cell of the memory cell array; and
the at least one memory cell comprises a semiconductor body and a storage structure arranged in the third direction.

20. The method of claim 19, wherein forming the conductive structures comprising:
providing a semiconductor structure having the bit lines extending along the first direction, wherein the bit lines are separated by sacrificial structures along the second direction, and wherein the sacrificial structures comprise a sacrificial material surrounded by a dielectric layer;
removing the sacrificial material in the sacrificial structures by an etching process to form first trenches; and
filling a conductive material into the first trenches to form the conductive structures.
